(19) United States
(12) Patent Application Publication
(10) Pub. No.: US 2026/0276159 A1
(43) Pub. Date: Sep. 17, 2026

(54) METHOD AND INTERNET OF THINGS SYSTEM FOR LIQUID ACCUMULATION SUPERVISION IN SMART GAS PIPELINES

(71) Applicant: CHENGDU QINCHUAN IOT TECHNOLOGY CO., LTD., Chengdu (CN)

(72) Inventors: Zehua SHAO, Chengdu (CN); Yong LI, Chengdu (CN); Yaqiang QUAN, Chengdu (CN); Yunbai CHEN, Chengdu (CN)

(73) Assignee: CHENGDU QINCHUAN IOT TECHNOLOGY CO., LTD., Chengdu (CN)

(21) Appl. No.: 19/669,965

(22) Filed: May 6, 2026

(30) Foreign Application Priority Data
Mar. 17, 2026 (CN) 202610327750.2

(51) Int. Cl. F17D 3/00; F16L 55/48; F16L 101/30

(52) U.S. Cl. CPC F17D 3/00; F16L 55/48; F16L 2101/30; G05B 2219/39001; G05B 2219/41108

(57) ABSTRACT

Provided is a method and an Internet of Things system for liquid accumulation supervision in smart gas pipelines. The system comprises: a gas company management platform, a gas company sensor network platform, and a gas device object platform; the gas company management platform is configured to: obtain gas sampling information; determine a cumulative transmission time; determine a liquid accumulation volume in an interior of the gas pipeline; determine a valve opening adjustment amount and control movement of a pressure regulating valve of a gas gate station based on the valve opening adjustment amount, or issue an instruction to the gas gate station to replace a filter element of a gas filtration device; and remotely control a liquid accumulation supervision device to open an automatic blowdown valve.

### CROSS-REFERENCE TO RELATED APPLICATIONS

This application claims priority to Chinese Patent Application No. 202610327750.2, filed on Mar. 17, 2026, the entire contents of which are hereby incorporated by reference.

### TECHNICAL FIELD

The present disclosure relates to the field of gas pipeline cleaning, and in particular, to a method and an Internet of Things system for liquid accumulation supervision in smart gas pipelines.

### BACKGROUND

During gas transportation, moisture in the gas cannot be completely removed. When factors such as fluctuations in ambient temperature are encountered during the gas transportation, liquid accumulation is likely to form in the gas transmission pipeline. If the liquid accumulation is not removed in time, fluctuations in gas flow rate and pressure will occur, thereby affecting normal gas supply. In addition, the liquid accumulation accelerates corrosion of the pipeline, shortens the service life of the pipeline, and significantly increases the operation and maintenance costs of the gas pipeline.

Existing methods for pipeline liquid accumulation supervision typically rely on on-site inspection and other means to determine the liquid accumulation volume in the interior of a gas pipeline, which is not only time-consuming and labor-intensive but also fails to promptly remove the liquid accumulation when it accumulates excessively, affecting the transportation efficiency of the gas pipeline and potentially posing risks to the safe use of gas.

Therefore, it is necessary to provide a method and an Internet of Things system for liquid accumulation supervision in smart gas pipelines, which can achieve monitoring and early warning of pipeline liquid accumulation, promptly remove liquid accumulation when there is excessive liquid accumulation in the pipeline, reduce operation and maintenance costs, and ensure the safety of the gas pipeline.

### SUMMARY

One or more embodiments of the present disclosure provide an Internet of Things system for liquid accumulation supervision in smart gas pipelines. The system comprises a gas company management platform, a gas company sensor network platform, and a gas device object platform; and the gas company management platform is configured to: obtain gas sampling information from a storage device in a gas gate station at an upstream of the gas pipeline, wherein the gas sampling information is obtained by a sampling device sampling at a gas valve; determine a cumulative transmission time based on a sampling time point automatically recorded and uploaded by a gas auxiliary facility; determine a liquid accumulation volume in an interior of the gas pipeline based on the gas sampling information and the cumulative transmission time and mark the liquid accumulation volume at positions of different pipeline models in the Geographic Information System (GIS); and in response to determining that the liquid accumulation volume in the interior of the gas pipeline increases to a preset volume threshold, determine a valve opening adjustment amount and control a pressure regulating valve of the gas gate station to move based on the valve opening adjustment amount to reduce a valve opening, or issue an instruction to the gas gate station to replace a filter element of a gas filtration device to reduce a liquid accumulation generation rate in the gas pipeline downstream of the gas gate station; and remotely control a liquid accumulation supervision device to open an automatic blowdown valve to reduce the liquid accumulation volume in the gas pipeline.

One or more embodiments of the present disclosure provides a method for liquid accumulation supervision in smart gas pipelines. The method is executed based on a gas company management platform, and the method comprises: obtaining gas sampling information from a storage device in a gas gate station at an upstream of the gas pipeline, wherein the gas sampling information is obtained by a sampling device sampling at a gas valve; determining a cumulative transmission time based on a sampling time point automatically recorded and uploaded by a gas auxiliary facility; determining a liquid accumulation volume in an interior of the gas pipeline based on the gas sampling information and the cumulative transmission time, and marking the liquid accumulation volume at positions of different pipeline models in a Geographic Information System (GIS); and in response to determining that the liquid accumulation volume in the interior of the gas pipeline increases to a preset volume threshold, determining a valve opening adjustment amount and controlling a pressure regulating valve of the gas gate station to move based on the valve opening adjustment amount to reduce a valve opening, or issuing an instruction to the gas gate station to replace a filter element of a gas filtration device to reduce a liquid accumulation generation rate in the gas pipeline downstream of the gas gate station; and remotely controlling a liquid accumulation supervision device to open an automatic blowdown valve to reduce the liquid accumulation volume in the gas pipeline.

### BRIEF DESCRIPTION OF THE DRAWINGS

This disclosure is further illustrated by way of exemplary embodiments, which is described in detail with reference to the accompanying drawings. These embodiments are not limiting, and in these embodiments, the same reference numerals denote the same structures, wherein:

FIG. 1 is a schematic diagram illustrating a platform structure of an Internet of Things system for liquid accumulation supervision in smart gas pipelines according to some embodiments of the present disclosure;

FIG. 2 is a flowchart illustrating an exemplary process of a method for liquid accumulation supervision in smart gas pipelines according to some embodiments of the present disclosure;

FIG. 3 is a flowchart illustrating an exemplary process for controlling the operation of an automatic blowdown valve in each of the liquid accumulation supervision devices according to some embodiments of the present disclosure;

FIG. 4 is a schematic diagram illustrating an exemplary process for determining a liquid accumulation volume in an interior of a gas pipeline according to some embodiments of the present disclosure;

FIG. 5 is a schematic diagram illustrating an exemplary pipeline liquid accumulation model according to some embodiments of the present disclosure.

### DETAILED DESCRIPTION

To more clearly illustrate the technical solutions of the embodiments of the present disclosure, the accompanying drawings to be used in the description of the embodiments are briefly introduced below. It is apparent that the accompanying drawings in the following description are merely some examples or embodiments of the present disclosure, and for a person of ordinary skill in the art, without inventive effort, the present disclosure can also be applied to other similar scenarios based on the accompanying drawings. Unless obvious from the context or otherwise specified, the same reference numerals in the drawings represent the same structures or operations.

As shown in the present disclosure and the claims, unless the context clearly indicates an exception, words such as ‘a’, ‘an’, ‘one’, and/or ‘the’ do not exclusively denote the singular, but may also include the plural. Generally speaking, the terms ‘comprises’ and ‘includes’ merely indicate the inclusion of specifically identified steps and elements, and these steps and elements do not constitute an exclusive list. A manner or a device may also include other steps or elements.

In the present disclosure, flowcharts are used to illustrate operations performed by a system according to embodiments of the present disclosure. It should be understood that preceding or succeeding operations are not necessarily performed precisely in sequence. Instead, the various steps may be processed in reverse order or concurrently. Meanwhile, other operations may also be added to these processes, or one or more operations may be removed from these processes.

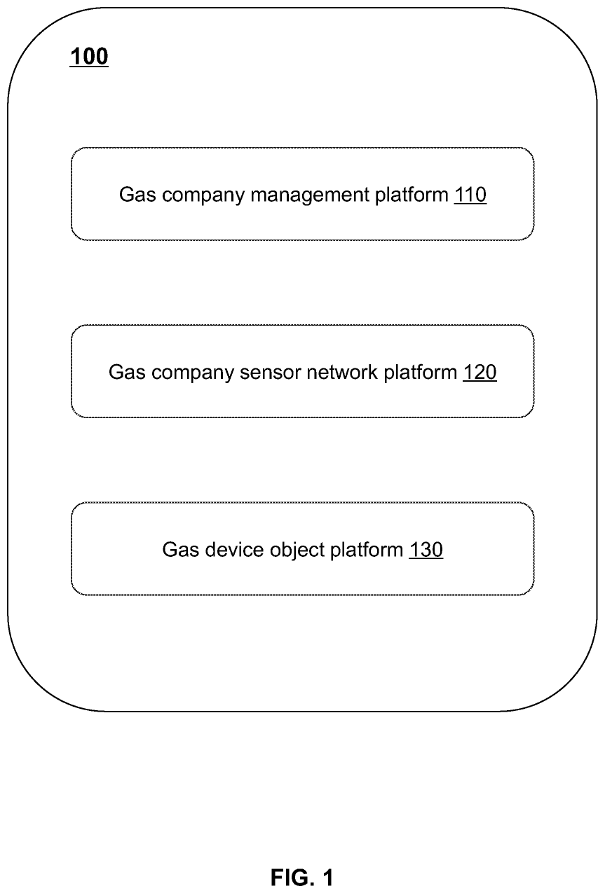

FIG. 1 is a schematic diagram illustrating a platform structure of an Internet of Things system for liquid accumulation supervision in smart gas pipelines according to some embodiments of the present disclosure.

In some embodiments, an Internet of Things system for liquid accumulation supervision in a smart gas pipeline 100 (hereinafter referred to as the IoT system 100) may comprise a gas company management platform 110, a gas company sensor network platform 120, and a gas device object platform 130 sequentially interacting.

The gas company management platform 110 may be a platform for overall planning and coordinating the connections and collaboration between the various functional platforms, aggregating all the information of the IoT system, and providing sensing management and control management functions for the operation of the IoT system. The gas company management platform 110 comprises a processor and a storage device.

The gas company sensor network platform 120 is a functional platform for managing sensing communication. In some embodiments, the gas company sensor network platform 120 comprises a wireless communication device.

The gas device object platform 130 is a platform for interacting with gas devices. In some embodiments, the gas device object platform 130 comprises gas devices such as a liquid accumulation supervision device, a pipeline robot, and a sampling device, or the like. The gas company management platform 110 may issue instructions to the gas devices of the gas device object platform 130 to control opening or closing of the liquid accumulation supervision device and control the sampling device to perform sampling.

The liquid accumulation supervision device refers to a device for discharging liquid accumulation in a gas pipeline. In some embodiments, the liquid accumulation supervision device comprises an automatic blowdown valve.

The automatic blowdown valve is a device that can be opened to discharge liquid accumulation in an interior of a gas pipeline. In some embodiments, the automatic blowdown valve automatically performs periodic activation according to an opening cycle.

In some embodiments, the gas company management platform 110 may also issue opening instructions to the automatic blowdown valve via the gas company sensor network platform 120 to remotely control the opening and closing of the automatic blowdown valve.

The pipeline robot is a device that travels in a gas pipeline and collects data. In some embodiments, the pipeline robot is configured with a force sensor, which can collect resistance data in a gas pipeline, and upload the resistance data to the gas company management platform 110 via the wireless communication device of the gas company sensor network platform.

The sampling device is a device for obtaining gas samples from a gas pipeline. The sampling device may obtain gas samples by sampling at a gas valve (e.g., a pressure regulating valve, a shunt valve, etc.), and obtain gas sampling information through detection by a gas analysis device.

In some embodiments of the present disclosure, the IoT system 100 can operate coordinately and regularly under the unified management of the gas company management platform to realize informatization and smartization of liquid accumulation detection and discharge in the gas pipeline.

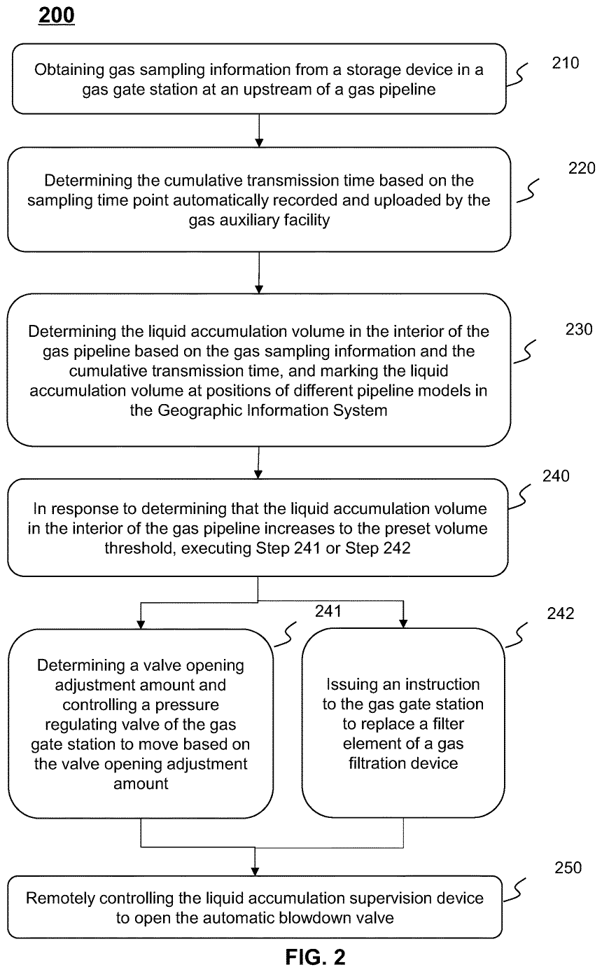

FIG. 2 is a flowchart illustrating an exemplary process of a method for liquid accumulation supervision in smart gas pipelines according to some embodiments of the present disclosure. As shown in FIG. 2, a process 200 comprises the following steps. In some embodiments, the process 200 may be executed by the gas company management platform.

Step 210, obtaining gas sampling information from a storage device in a gas gate station at an upstream of a gas pipeline.

The sampling device obtains gas sampling information by sampling at the gas valve.

The gas gate station is a facility in a gas pipeline network for monitoring and regulating gas in a gas pipeline. In some embodiments, the gas gate station may comprise the gas valve, a gas filtration device, the storage device, and the sampling device. More content about the gas filtration device may refer to relevant descriptions below.

The gas sampling information can reflect the physicochemical characteristics of the gas. In some embodiments, the gas sampling information includes but is not limited to gas components, water content, or the like.

In some embodiments, gas sampling information at a plurality of different time points may form a sequence, and each of the gas pipelines may have a corresponding gas sampling information sequence.

In some embodiments, the sampling device may obtain gas samples by sampling at the gas valve and obtain gas sampling information through detection by the gas analysis device. The gas sampling information may be stored in the storage device of the gas gate station for the gas company management platform to retrieve as needed.

Step 220, determining the cumulative transmission time based on the sampling time point automatically recorded and uploaded by the gas auxiliary facility.

The gas auxiliary facility refers to an auxiliary facility that provides support and guarantee for normal operation of gas facilities. In some embodiments, the gas auxiliary facility comprises a gas analysis device, a liquid accumulation supervision device, and a pipeline robot. The gas analysis device may include a moisture meter, a chromatograph, or the like.

For more content regarding the liquid accumulation supervision device and the pipeline robot, please refer to the related description of FIG. 1.

In some embodiments, the gas auxiliary facility may automatically record the sampling time point and upload the sampling time point to the gas company management platform as needed.

The sampling time point refers to the time point at which the sampling device performs sampling. In some embodiments, the sampling time point may be determined based on actual application scenarios and needs.

The cumulative transmission time refers to a total transmission time of the gas pipeline elapsed since the last liquid accumulation cleaning.

In some embodiments, the gas company management platform may determine the cumulative transmission time through a plurality of manners. For example, the gas company management platform may determine the cumulative transmission time based on the sampling time point automatically recorded and uploaded by the auxiliary facility. The gas company management platform may obtain all the sampling time points from the sampling time point of the last liquid accumulation cleaning to the current moment, calculate the time intervals between the adjacent sampling time points, remove the time intervals when the gas pipeline stops transporting gas, and determine a sum of the remaining time intervals as the cumulative transmission time.

In some embodiments, the cumulative transmission time may also be preset based on prior experience.

Step 230, determining the liquid accumulation volume in the interior of the gas pipeline based on the gas sampling information and the cumulative transmission time, and marking the liquid accumulation volume at positions of different pipeline models in the Geographic Information System (GIS).

The liquid accumulation volume refers to a volume of accumulated water in the gas pipeline.

The GIS refers to a geographic information system used for representing the spatial structure of a gas pipeline network, including three-dimensional models of different gas pipelines and the gas gate station. The GIS can reflect operating status, location coordinates, orientation, upstream-downstream relationship, or the like of different gas pipelines and the gas gate station.

In some embodiments, the gas company management platform may mark a gas pipeline having liquid accumulation and the liquid accumulation volume of the gas pipeline in the GIS.

In some embodiments, the gas pipeline may correspond to the automatic blowdown valve. The gas company management platform may define the gas pipeline segment between two adjacent automatic blowdown valves as a pipeline segment whose liquid accumulation discharge is undertaken by the downstream automatic blowdown valve of the two adjacent automatic blowdown valves.

In some embodiments, the gas company management platform may obtain a plurality of historical time intervals based on historical sampling time points, determine the liquid accumulation change rate corresponding to each of historical time intervals based on historical transmission data, then determine the liquid accumulation volume of each historical time interval, and obtain the current liquid accumulation volume in the interior of the gas pipeline by summing the liquid accumulation volumes of all the historical time intervals from the last liquid accumulation cleaning to the current moment.

Exemplarily, the liquid accumulation volume may be determined by formula (1):

$$H = {t}_{1} \times {k}_{1} + {t}_{2} \times {k}_{2} + … + {t}_{n} \times {k}_{n} . \qquad ( 1 )$$

In the formula, H denotes the liquid accumulation volume, tₙ denotes the n-th historical time interval, and kₙ denotes the liquid accumulation change rate corresponding to the n-th historical time interval. For more content regarding the historical time interval, please refer to the related description above.

The liquid accumulation change rate refers to a growth rate of liquid accumulation in the gas pipeline. In some embodiments, the liquid accumulation change rate is positively correlated with the gas moisture content in the gas sampling information.

In some embodiments, the gas company management platform may also determine the liquid accumulation change rate of the current gas pipeline by querying the liquid accumulation change rate table based on the current gas sampling information and the pipeline number.

In some embodiments, the liquid accumulation change rate table includes different historical gas sampling information and historical liquid accumulation change rates corresponding to different historical pipeline numbers. The gas company management platform may construct the liquid accumulation change rate table based on historical data. For example, the gas company management platform may obtain historical gas sampling information, a historical liquid accumulation supervision amount, and a historical liquid accumulation supervision cycle corresponding to a historical gas pipeline, and determine the historical liquid accumulation change rate of the gas pipeline based on the historical liquid accumulation supervision amount and the historical liquid accumulation supervision cycle. The gas company management platform may repeat the above operations to obtain historical liquid accumulation change rates of a plurality of gas pipelines under different historical gas sampling information, thereby constructing the liquid accumulation change rate table.

In some embodiments, the gas company management platform may also select historical gas sampling information having the same pipeline number and a similarity of gas sampling information greater than a similarity threshold from the liquid accumulation change rate table based on similarity matching, and determine the historical liquid accumulation change rate corresponding to the historical gas sampling information as the currently required liquid accumulation change rate.

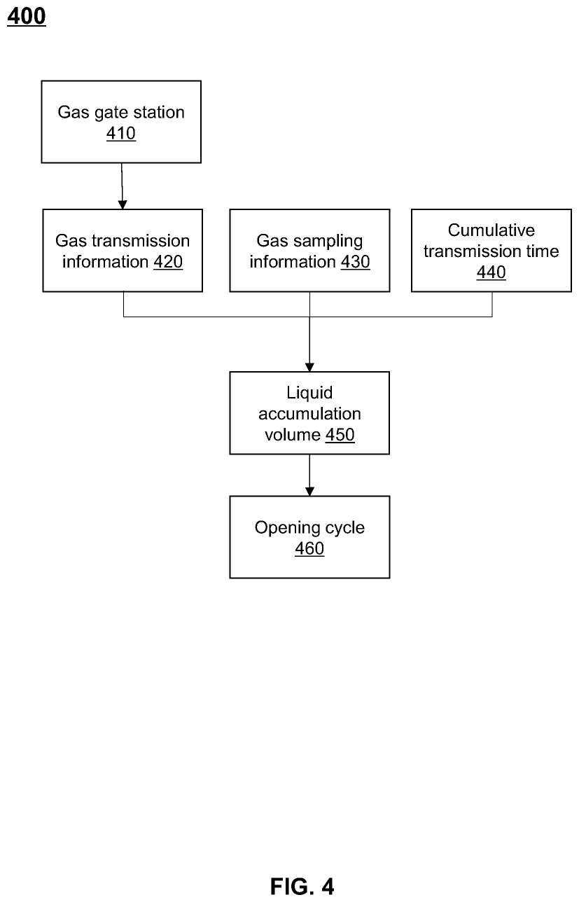

In some embodiments, the gas company management platform may also determine the liquid accumulation volume based on the gas transmission information, the gas sampling information, and the cumulative transmission time. For content regarding this portion, please refer to FIG. 4 and its related description.

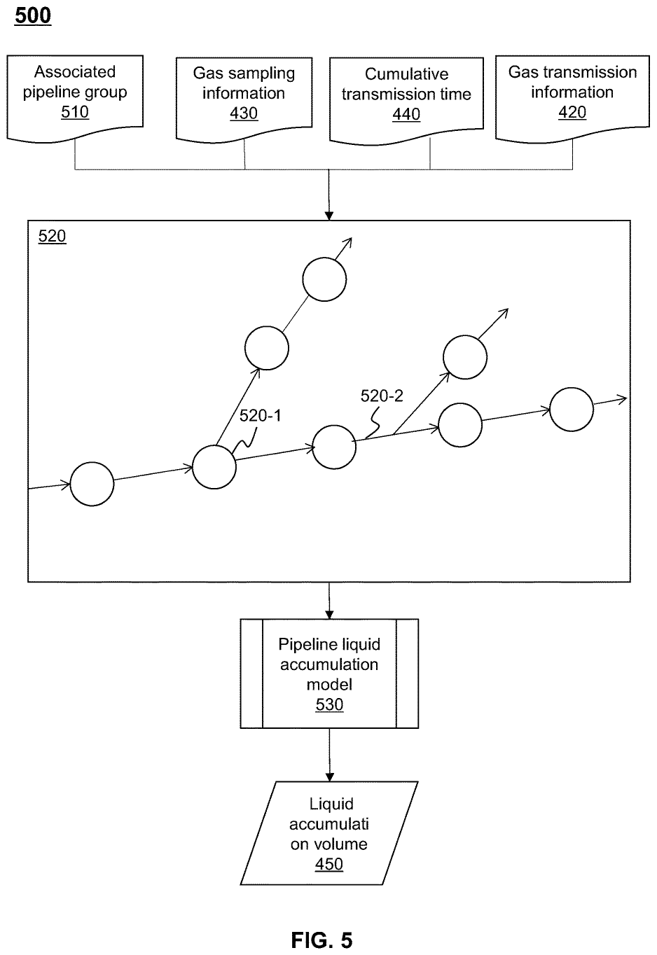

In some embodiments, the gas company management platform may also determine the liquid accumulation volume through a pipeline liquid accumulation model. For content regarding this portion, please refer to FIG. 5 and its related description.

Step 240, in response to determining that the liquid accumulation volume in the interior of the gas pipeline increases to the preset volume threshold, executing Step 241 or Step 242.

The preset volume threshold refers to a critical value at which the accumulated liquid accumulation affects normal gas transmission. In some embodiments, the preset volume threshold may be preset based on prior experience.

Step 241, determining a valve opening adjustment amount and controlling a pressure regulating valve of the gas gate station to move based on the valve opening adjustment amount.

The valve opening refers to an opening magnitude of the pressure regulating valve. The larger valve opening indicates the larger gas flow rate. The valve opening adjustment amount includes an adjustment magnitude and an adjustment direction of the valve opening (for example, increasing the valve opening or decreasing the valve opening).

In some embodiments, the valve opening of the pressure regulating valve may be negatively correlated with a magnitude by which the liquid accumulation volume exceeds the preset volume threshold. The larger magnitude by which the preset volume threshold is exceeded indicates that the current gas pipeline is more congested, and it is more prone to phenomena such as pressure accumulation, and the safety hazard is greater for normal gas transmission. Therefore, it is necessary to reduce the valve opening of the pressure regulating valve to avoid excessive local pressure in the gas pipeline, so as to avoid accidents. When the magnitude by which the liquid accumulation volume is below the preset volume threshold is larger, it indicates that the current gas pipeline is relatively unobstructed. At this time, the valve opening of the pressure regulating valve may be appropriately increased to facilitate the smooth transportation of gas.

In some embodiments, the gas company management platform may send the valve opening adjustment amount to the gas gate station to increase or decrease the valve opening and control the gas transmission flow rate.

Step 242, issuing an instruction to the gas gate station to replace a filter element of a gas filtration device.

The gas filtration device refers to a device for filtering and purifying gas. In some embodiments, after the gas gate station receives the instruction to replace the filter element of the gas filtration device, the gas gate station can improve the effect of removing moisture and impurities from the gas by replacing the filter element, so as to reduce the liquid accumulation generation rate in the gas pipeline downstream of the gas gate station.

In some embodiments, when the filter element of the gas filtration device can filter normally, the gas company management platform may execute Step 241; and when the filter element cannot filter normally, the gas company management platform may execute Step 242.

Step 250, remotely controlling the liquid accumulation supervision device to open the automatic blowdown valve.

In some embodiments, when the liquid accumulation volume in the interior of the gas pipeline increases to the preset volume threshold, the gas company management platform may issue an instruction to the liquid accumulation supervision device to open the automatic blowdown valve, so as to remove the liquid accumulation in the gas pipeline.

In some embodiments, the gas company management platform may determine an opening time point of the automatic blowdown valve in a plurality of manners. For example, the opening time point of the automatic blowdown valve may be preset.

In some embodiments, the gas company management platform may determine the opening time point of the automatic blowdown valve of the liquid accumulation supervision device in each of the gas pipelines based on the liquid accumulation volume in the interior of the gas pipeline.

In some embodiments, the gas company management platform may determine the opening time point of the automatic blowdown valve based on the liquid accumulation volume in the interior of the gas pipeline in a plurality of manners. For example, the gas company management platform may determine an estimated time interval for the liquid accumulation volume to reach the preset volume threshold based on the liquid accumulation volume in the interior of the gas pipeline and a current liquid accumulation change rate in the interior of the gas pipeline, and determine the opening time point based on a current time and the estimated time interval. For more content regarding determining the liquid accumulation volume, please refer to Step 230 and related content above.

In some embodiments, the gas company management platform may determine the opening sequence based on the opening time points. For example, the gas company management platform may sort the opening time points of different gas pipelines from earliest to latest to obtain the opening sequence.

In some embodiments, the gas company management platform may sequentially remotely open the automatic blowdown valve of the corresponding liquid accumulation supervision device based on the opening sequence to discharge the liquid accumulation in the gas pipeline.

In some embodiments, the gas company management platform may activate the to-be-activated liquid accumulation supervision device of the to-be-constructed gas pipeline based on the liquid accumulation volume data in the interior of the gas pipeline and the opening record of the automatic blowdown valve of the liquid accumulation supervision device.

The liquid accumulation volume data can reflect the liquid accumulation volume in the gas pipeline. For example, the liquid accumulation volume data may comprise the liquid accumulation volume. In some embodiments, the gas company management platform may determine the volume of the liquid accumulation discharged from the gas pipeline as the liquid accumulation volume data of the gas pipeline.

The opening record refers to a log record of the opening of the automatic blowdown valve of the liquid accumulation supervision device. The opening record may comprise the opening time point of the automatic blowdown valve, an opening duration of the automatic blowdown valve, or the like.

The to-be-constructed gas pipeline refers to a gas pipeline that is being constructed or has been constructed but not yet been put into use. The to-be-activated liquid accumulation supervision device refers to a liquid accumulation supervision device in the to-be-constructed gas pipeline that has not yet been activated (i.e., it is in a standby state and has not yet been connected to an IoT system).

In some embodiments, the gas company management platform may determine the to-be-activated liquid accumulation supervision device that needs to be activated in the to-be-constructed gas pipeline based on the liquid accumulation volume data and the opening record. For example, the gas company management platform may determine, from the GIS, an in-use gas pipeline connected to the to-be-constructed gas pipeline. The opening of the gas pipeline is more frequent, and the liquid accumulation volume is greater, it indicates that the more liquid accumulation is generated in the interior of the to-be-constructed gas pipeline after it is put into use. Therefore, a greater number of to-be-activated liquid accumulation supervision devices need to be activated in the to-be-constructed gas pipeline to ensure that the to-be-constructed gas pipeline can stably operate in the future.

In some embodiments of the present disclosure, by remotely controlling the automatic opening and closing of the liquid accumulation supervision devices of different gas pipelines, the liquid accumulation in the gas pipeline can be supervised timely and effectively to ensure the stability of gas transmission; based on the opening record of the gas pipeline, the liquid accumulation volume in the gas pipeline may be determined, thereby determining the quantity of the to-be-activated liquid accumulation supervision devices to ensure the normal operation of the to-be-constructed gas pipeline.

In some embodiments, the gas company management platform may determine the opening sequence of the automatic blowdown valve of each of the liquid accumulation supervision devices at a future time point based on the estimated liquid accumulation volume.

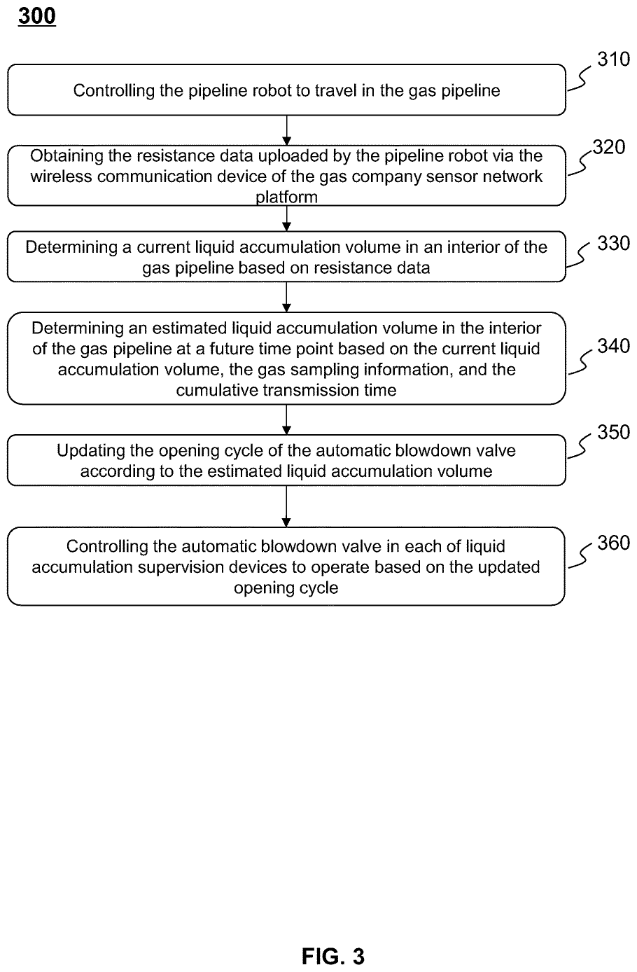

In some embodiments, the gas company management platform may determine an estimated opening time point of the gas pipeline based on the estimated liquid accumulation volume. The step for determining the estimated opening time point is similar to that for determining the opening time point, please refer to the related descriptions above. For more content regarding the estimated liquid accumulation volume, refer to FIG. 3 and the related descriptions thereof.

In some embodiments, the gas company management platform may determine a gas pipeline group to which the gas pipeline belongs, and adjust the opening sequence of the automatic blowdown valve based on the gas pipeline group to obtain the opening sequence of the automatic blowdown valve of each of the liquid accumulation supervision devices at the future time point. For example, the gas company management platform may determine a plurality of gas pipeline groups, each gas pipeline group including a plurality of gas pipelines and a plurality of the automatic blowdown valves, sort the automatic blowdown valves within each gas pipeline group according to the opening time point to obtain the opening sequence of the automatic blowdown valve in each of the gas pipeline groups, wherein the opening time point is closer to a current time point, the ranking is higher. When the liquid accumulation needs to be discharged, at most one automatic blowdown valve with the highest opening sequence (i.e., the foremost in order) is selected from each gas pipeline group for opening. For more content regarding determining the gas pipeline group, refer to FIG. 4 and the related descriptions thereof.

In some embodiments of the present disclosure, the discharge of the liquid accumulation from the gas pipeline affects the gas pressure, the gas flow velocity, or the like in the gas pipeline. When a plurality of the gas pipelines in an area discharge the liquid accumulation simultaneously, it causes a certain impact on the normal transmission of gas. By dividing gas pipelines into a plurality of gas pipeline groups and allowing at most one gas pipeline in each gas pipeline group to perform blowdown simultaneously, the stability of gas transmission can be ensured to prevent large fluctuations in the gas.

In some embodiments of the present disclosure, by automatically recording and uploading the sampling time point, combined with the gas sampling information, the gas company management platform can accurately determine the cumulative transmission time, and determine the liquid accumulation volume in the interior of the gas pipeline accordingly, to achieve automated monitoring and improve transmission efficiency. When the liquid accumulation volume in the interior of the gas pipeline increases to the preset volume threshold, the gas company management platform may automatically determine the valve opening adjustment amount and control the pressure regulating valve to move, or issue an instruction to replace a filter element, thereby effectively reducing a liquid accumulation generation rate and preventing safety hazards caused by excessive liquid accumulation.

FIG. 3 is a flowchart illustrating an exemplary process for determining the opening cycle of the automatic blowdown valve according to some embodiments of the present disclosure. As shown in FIG. 3, the process 300 comprises the following steps. In some embodiments, the process 300 may be executed by the gas company management platform 110.

Step 310, controlling the pipeline robot to travel in the gas pipeline.

The pipeline travel path of the pipeline robot in the gas pipeline may be determined in a plurality of manners. For example, the pipeline travel path may be preset based on prior experience.

In some embodiments, the gas company management platform may determine the pipeline travel path of the pipeline robot based on the opening cycle of the automatic blowdown valve.

The pipeline travel path may reflect a travel sequence of the pipeline robot in the gas pipeline. In some embodiments, the pipeline travel path may be represented as sequence data composed of pipeline numbers and pipeline location coordinates in the GIS. Exemplarily, the pipeline travel path may be represented as ‘[number A1, coordinate S1; number A2, coordinate S2; number A3, coordinate S3]’, which indicates that the pipeline robot sequentially travels through the gas pipelines with numbers A1, A2, and A3.

In some embodiments, the gas company management platform may determine the pipeline travel path based on the remaining time until the next opening cycle of the automatic blowdown valve. For example, the gas company management platform may obtain a historical time point of a previous liquid discharge of the gas pipeline, and determine the remaining time until a next liquid discharge based on the opening cycle of the automatic blowdown valve. The gas company management platform sorts the remaining opening time from shortest to longest, selects a preset quantity of the automatic blowdown valves, and generates the pipeline travel path passing through these automatic blowdown valves in the GIS.

In some embodiments, when the generated pipeline travel path needs to pass through the gas pipeline that does not include the preset quantity of automatic blowdown valves, resistance data collection may be performed on the gas pipeline being passed through. For descriptions regarding the resistance data, please refer to FIG. 1 and related content thereof.

In some embodiments, the preset quantity may be preset based on prior experience. Moreover, for example, the preset quantity may be positively correlated with a remaining power of the pipeline robot.

For more content regarding the pipeline robot, refer to FIG. 1 and the related descriptions thereof.

Step 320, obtaining the resistance data uploaded by the pipeline robot via the wireless communication device of the gas company sensor network platform.

The resistance data can characterize a magnitude of resistance encountered by the pipeline robot due to the liquid accumulation when traveling in the pipeline. The resistance data may comprise the magnitude of resistance encountered by the pipeline robot and the pipeline number where the resistance is encountered.

Step 330, determining a current liquid accumulation volume in an interior of the gas pipeline based on resistance data.

The current liquid accumulation volume refers to the liquid accumulation volume in the gas pipeline at a current time point.

In some embodiments, the gas company management platform may determine the current liquid accumulation volume in the interior of the gas pipeline based on the resistance data. For example, the current liquid accumulation volume is positively correlated with the resistance data of the pipeline robot.

In some embodiments, the gas company management platform may also determine the current liquid accumulation volume of the gas pipeline by querying a resistance preset table based on the resistance data. The resistance preset table includes different reference resistance data and corresponding reference liquid accumulation volumes for different reference pipeline numbers.

In some embodiments, the gas company management platform may construct the resistance preset table based on historical data. For example, for a certain historical gas pipeline, the gas company management platform may obtain a pipeline number, historical resistance data, and historical liquid accumulation volume of the pipeline, and use them as a reference pipeline number, reference resistance data, and a corresponding reference liquid accumulation volume. The gas company management platform may repeat the above operations to obtain reference pipeline numbers, reference resistance data, and corresponding reference liquid accumulation volumes of other historical gas pipelines, and construct the resistance preset table.

In some embodiments, when the current liquid accumulation volume needs to be determined, the gas company management platform may select a reference liquid accumulation volume that has the same pipeline number and a resistance data similarity greater than a similarity threshold from the resistance preset table based on similarity matching, and determine the selected reference liquid accumulation volume as the current liquid accumulation volume.

Step 340, determining an estimated liquid accumulation volume in the interior of the gas pipeline at a future time point based on the current liquid accumulation volume, the gas sampling information, and the cumulative transmission time.

The estimated liquid accumulation volume refers to a predicted liquid accumulation volume at a future time point. For specific descriptions of the gas sampling information and the cumulative transmission time, please refer to related content in FIG. 2.

In some embodiments, the gas company management platform may add the current liquid accumulation volume and a newly generated liquid accumulation volume from a current time point to a future time point to obtain the estimated liquid accumulation volume.

In some embodiments, the newly generated liquid accumulation volume may be determined based on the time interval from the current time point to the future time point and an estimated liquid accumulation change rate, and the estimated liquid accumulation change rate may be preset based on prior experience or may be the current liquid accumulation change rate. The time interval from the current time point to the future time point and the estimated liquid accumulation change rate are similar to the cumulative transmission time and the liquid accumulation change rate in Step 230 of FIG. 2, respectively, and the liquid accumulation volume may be determined based on the time interval and the estimated liquid accumulation change rate in a manner similar to that in Step 230 of FIG. 2.

Step 350, updating the opening cycle of the automatic blowdown valve according to the estimated liquid accumulation volume.

In some embodiments, the automatic blowdown valve may be periodically activated according to the opening cycle, and the automatic blowdown valve may also be activated after receiving an opening instruction. The opening cycle refers to a time interval between two adjacent openings of the automatic blowdown valve.

In some embodiments, the gas company management platform may obtain the time interval between a time point when the pipeline robot travels and a time point of the last opening of the automatic blowdown valve, determine a current liquid accumulation change rate based on a ratio of the current liquid accumulation volume to the time interval, determine a duration for liquid accumulation to re-accumulate to the preset volume threshold after liquid accumulation supervision based on the preset volume threshold and the current liquid accumulation change rate, and determine the duration as the updated opening cycle of the automatic blowdown valve.

Step 360, controlling the automatic blowdown valve in each of liquid accumulation supervision devices to operate based on the updated opening cycle.

In some embodiments, the gas company management platform may issue the updated opening cycle to the liquid accumulation supervision device, so that the automatic blowdown valve may regularly discharge the liquid accumulation according to the opening cycle.

In some embodiments of the present disclosure, the use of the pipeline robot can improve the degree of automation, also remotely obtain pipeline liquid accumulation-related information, and concurrently ensure the safety of operators. By optimizing the pipeline travel path of the pipeline robot, the acquisition efficiency of the pipeline liquid accumulation information can be improved.

FIG. 4 is a schematic diagram illustrating an exemplary process for determining the liquid accumulation volume in the interior of the gas pipeline according to some embodiments of the present disclosure.

In some embodiments, the gas company management platform is further configured to: obtain the gas transmission information 420 from the gas gate station 410 through the gas company sensor network platform; generate an associated pipeline group based on gas pipelines, and mark pipeline models in the GIS; determine the liquid accumulation volume 450 in the interior of each of the gas pipelines in the associated pipeline group based on the gas transmission information 420, the gas sampling information 430, and the cumulative transmission time 440; and jointly regulate the opening cycle 460 of each of the automatic blowdown valves included in the associated pipeline group according to the liquid accumulation volume 450.

In some embodiments, the gas company management platform may obtain the gas transmission information 420 from the gas gate station 410 through the gas company sensor network platform.

The gas transmission information 420 can reflect transmission situation of the gas. For example, the gas transmission information 420 may include a gas transmission rate and a gas temperature.

In some embodiments, the gas company management platform may obtain the gas transmission information 420 by analyzing gas samples based on the gas analysis device of the gas gate station 410. For more content regarding the gas samples, please refer to FIG. 2 and related content.

In some embodiments, the gas company management platform may generate an associated pipeline group based on gas pipelines, and mark pipeline models in the GIS.

The associated pipeline group refers to a set of gas pipelines having a pipeline connectivity relationship. By way of example, a main pipeline A includes three first-level branch pipelines A1, A2, and A3, and the downstream section of the first-level branch pipeline A1 also includes two second-level branch pipelines A11 and A12, then pipelines A, A1, and A11 may form an associated pipeline group; and pipelines A, A1, and A12 may form another associated pipeline group.

In some embodiments, the gas company management platform may determine the liquid accumulation volume 450 in the interior of each of the gas pipelines in the associated pipeline group based on the gas transmission information 420, the gas sampling information 430, and the cumulative transmission time 440.

In some embodiments, the gas company management platform may obtain the liquid accumulation change rate of each of the gas pipelines in the associated pipeline group by querying the liquid accumulation change rate table based on the gas sampling information 430. For the description of the liquid accumulation change rate table, please refer to FIG. 2 and related content thereof.

In some embodiments, the gas company management platform may determine a liquid accumulation coefficient based on the liquid accumulation change rate of each of the gas pipelines. The liquid accumulation coefficient can reflect a multiplier relationship between liquid accumulation change rates of two different gas pipelines. For example, a ratio of the liquid accumulation change rates of two gas pipelines is determined as the liquid accumulation coefficient between the two gas pipelines. A large number of liquid accumulation coefficients may be stored in the storage device of the gas company management platform in a matrix form.

In some embodiments, the gas company management platform may determine the liquid accumulation change rate of each of other gas pipelines in the associated pipeline group based on the liquid accumulation change rate of the current gas pipeline and the corresponding liquid accumulation coefficients of the gas pipeline and the other gas pipelines in the associated pipeline group, and determine the liquid accumulation volume 450 of each of all gas pipelines in the associated pipeline group based on the liquid accumulation change rate and the cumulative transmission time 440 corresponding to each of the gas pipelines.

In some embodiments, the gas company management platform may jointly regulate the opening cycle 460 of each of the automatic blowdown valves included in the associated pipeline group according to the liquid accumulation volume 450.

Regarding the step of jointly regulating the opening cycle 460 of each of the automatic blowdown valves included in the associated pipeline group according to the liquid accumulation volume 450, it is similar to the step of updating the opening cycle of the automatic blowdown valve according to the estimated liquid accumulation volume in FIG. 3, and reference may be made to related content of Step 360 and Step 350 of FIG. 3.

In some embodiments of the present disclosure, by generating an associated pipeline group based on gas pipelines and marking in the GIS, it cany accurately infer the liquid accumulation volume 450 of each of other gas pipelines based on data of some gas pipelines, which helps to solve the problem that it is difficult to determine the liquid accumulation volume 450 when the related data of the gas pipelines is incomplete.

In some embodiments, the gas company management platform is further configured to: determine a liquid accumulation coefficient of each of the gas pipelines based on an adjacency degree of a gas pipeline in the associated pipeline group to the most upstream pipeline, a liquid accumulation change rate of each of the gas pipelines, and the gas transmission information 420; and determine the liquid accumulation volume 450 in the interior of each of the gas pipelines in the associated pipeline group based on the cumulative transmission time 440, the liquid accumulation change rate, and the liquid accumulation coefficient.

The most upstream pipeline refers to the gas pipeline located at the most upstream position in the associated pipeline group. In some embodiments, the most upstream pipeline may be a gas pipeline directly connected to the gas gate station 410.

The adjacency degree can reflect the number of gas pipelines passing through the shortest path between two gas pipelines. For example, for gas pipeline A→gas pipeline A1→gas pipeline A11, the adjacency degree between gas pipeline A and gas pipeline A11 is 2.

In some embodiments, when a gas pipeline has a plurality of most upstream pipelines, the gas pipeline may have a plurality of adjacency degrees between the gas pipeline and the plurality of most upstream pipelines.

In some embodiments, the gas company management platform may obtain the liquid accumulation change rate of the most upstream gas pipeline in the associated pipeline group by querying the liquid accumulation change rate table based on the gas sampling information 430 of the most upstream gas pipeline. For the description of the liquid accumulation change rate table, please refer to FIG. 2 and related description thereof.

In some embodiments, the gas company management platform may determine the liquid accumulation change rate of a downstream gas pipeline based on the gas transmission information 420 and the liquid accumulation change rate of the most upstream gas pipeline.

In some embodiments, the liquid accumulation change rate of the downstream gas pipeline may be positively correlated with the liquid accumulation change rate of the most upstream gas pipeline, and negatively correlated with the adjacency degree of the downstream gas pipeline to the most upstream gas pipeline.

For example, the liquid accumulation change rate of the downstream pipeline may be obtained according to formula (2):

$${V}_{D} = {V}_{U} \times ( ( {V}_{0} / {V}_{D} ) \times {k}_{V} + ( {T}_{1} / {T}_{D} ) \times {k}_{D} ) \times {e}^{1 - P} . \qquad ( 2 )$$

In the formula, V_{D} denotes the liquid accumulation change rate of the downstream pipeline, V_{U} denotes the liquid accumulation change rate of the most upstream pipeline, V₀ denotes a reference flow velocity, V_{D} denotes a current gas flow rate of the downstream pipeline, T_{D} denotes a current gas temperature of the downstream pipeline, To denotes a reference temperature, P denotes the adjacency degree of the downstream gas pipeline to the most upstream gas pipeline, and k_{V} and k_{D} are coefficients. k_{V}≥0, k_{D}≥0, and k_{V}+k_{D}=1; the reference flow rate V₀ and the reference temperature T₀ may be preset based on prior experience.

In some embodiments, the reference flow rate V₀ and the reference temperature T₀ may be an average transmission flow velocity and an average transmission temperature of a plurality of gas pipelines in the associated pipeline group. The gas company management platform may obtain the gas transmission information from the gas gate station, and further obtain data such as the transmission flow velocity and the transmission temperature for each of a plurality of gas pipelines in the associated pipeline group, and statistically determine the average transmission flow velocity and the average transmission temperature.

In some embodiments, the gas company management platform determines the liquid accumulation volume 450 in the interior of each of the gas pipelines in the associated pipeline group based on the cumulative transmission time 440, the liquid accumulation change rate, and the liquid accumulation coefficient.

In some embodiments, the gas company management platform may determine the liquid accumulation change rate of each of other gas pipelines in the associated pipeline group based on a gas pipeline with the determined liquid accumulation change rate, and the liquid accumulation coefficients corresponding to the other gas pipelines in the associated pipeline group relative to the gas pipeline; and determine the liquid accumulation volume 450 of each of the gas pipelines in the associated pipeline group based on the liquid accumulation change rate and the cumulative transmission time 440.

For example, when the associated pipeline group includes three gas pipelines A1, A2, and A3, and given the liquid accumulation change rate of gas pipeline A1 and the liquid accumulation coefficient of gas pipeline A2 relative to gas pipeline A1, the liquid accumulation volume of gas pipeline A2 may be determined by formula (3):

$${L}_{A 2} = {M}_{A 1} \times K \times {S}_{A 2} . \qquad ( 3 )$$

In the formula, L_{A2} denotes the liquid accumulation volume of gas pipeline A2, M_{A1} denotes the liquid accumulation change rate of gas pipeline A1, K denotes the liquid accumulation coefficient of gas pipeline A2 relative to gas pipeline A1, and S_{A2} denotes the cumulative transmission time of gas pipeline A2.

In some embodiments, when a downstream gas pipeline has mechanical connectivity with a plurality of most upstream gas pipelines, a sum of the liquid accumulation volumes of the downstream gas pipeline relative to the plurality of most upstream gas pipelines may be generated based on the liquid accumulation coefficients of the downstream gas pipeline relative to the plurality of most upstream gas pipelines and the cumulative transmission time, and the sum may be determined as the final liquid accumulation volume of the downstream gas pipeline.

In some embodiments, according to the liquid accumulation volume, the gas company management platform jointly regulates the opening cycle 460 of each of the automatic blowdown valves included in the associated pipeline group. More description regarding regulating the opening cycle 460 may be found in FIG. 3 and related content thereof.

In some embodiments of the present disclosure, by determining the liquid accumulation coefficients of different gas pipelines, the liquid accumulation volume 450 in the interior of each of the gas pipelines in the associated pipeline group is further determined. This avoids requiring data acquisition and processing for all gas pipelines in the associated pipeline group. Only a portion of the data needs to be acquired to infer the liquid accumulation volume 450 in the entire associated pipeline group, which helps improve the determination efficiency of the IoT system.

FIG. 5 is a schematic diagram illustrating an exemplary pipeline liquid accumulation model according to some embodiments of the present disclosure.

In some embodiments, the gas company management platform is further configured to: construct the pipeline graph 520 based on the associated pipeline group 510, the gas sampling information 430, the cumulative transmission time 440, and the gas transmission information 420 corresponding to each of the gas pipelines in the associated pipeline group 510; and determine the liquid accumulation volume 450 of each of the gas pipelines in the associated pipeline group 510 based on the pipeline graph 520 via the pipeline liquid accumulation model 530, the pipeline liquid accumulation model 530 being a machine learning model.

The pipeline graph 520 refers to a knowledge graph representing the arrangement of gas pipelines. The pipeline graph 520 can reflect the distribution relationship between liquid accumulation supervision devices and gas pipelines.

The pipeline graph 520 may be composed of at least one node and at least one edge, a node corresponds to the liquid accumulation supervision device in a gas pipeline, and an attribute of the node may include the gas transmission information 420 and a current liquid accumulation volume. More content regarding the gas transmission information 420 may be found in FIG. 4 and related content thereof. More content regarding determining the current liquid accumulation volume may be found in step 330 of FIG. 3.

In some embodiments, an attribute of a node in the pipeline graph further comprises a historical liquid accumulation volume when the pipeline robot collects resistance data. The historical liquid accumulation volume refers to the liquid accumulation volume acquired at a historical time point. The gas company management platform may obtain the historical liquid accumulation volume from a storage device of the gas gate station.

In some embodiments, an edge corresponds to a gas pipeline between the nodes. The edge may be a directed edge, the direction of the edge represents the gas transmission direction, and the length of the edge can reflect the actual length of the gas pipeline. When a gas pipeline exists between two nodes, the nodes are connected by an edge.

In some embodiments, an attribute of the edge comprises the gas sampling information 430, the cumulative transmission time 440, a number of the associated pipeline group 510, and an adjacency degree to the most upstream pipeline.

In some embodiments, the gas company management platform may construct the pipeline graph 520 based on the associated pipeline group 510, the gas sampling information 430, the cumulative transmission time 440, and the gas transmission information 420 corresponding to the gas pipeline in the associated pipeline group 510.

In some embodiments, the gas company management platform may determine the liquid accumulation volume 450 of each of the gas pipelines in the associated pipeline group 510 based on the pipeline liquid accumulation model 530.

The pipeline liquid accumulation model 530 refers to a prediction model used for determining the liquid accumulation volume of a node. In some embodiments, the pipeline liquid accumulation model 530 may be a machine learning model. For example, the pipeline liquid accumulation model 530 may include any one or combination of a Graph Neural Networks (GNN) model or other customized model structures, or the like.

In some embodiments, an input of the pipeline liquid accumulation model 530 comprises the pipeline graph 520, and an output of the pipeline liquid accumulation model 530 comprises the liquid accumulation volume 450 of each of the gas pipelines in the associated pipeline group 510.

The pipeline liquid accumulation model 530 may be obtained through model training. The gas company management platform may obtain the pipeline liquid accumulation model 530 by training based on a large number of training samples with labels.

The training samples may include a sample pipeline graph, and the labels are the liquid accumulation volumes 450 of different nodes. In some embodiments, the training samples and the labels may be determined based on historical data. For example, the gas company management platform may construct the sample pipeline graph based on the pipeline models of the GIS and historical transmission data, use historical gas transmission information and a historical liquid accumulation volume at a first time point as the sample node attribute, use historical gas sampling information and historical cumulative transmission time as the sample edge attribute, and use the historical liquid accumulation volume at a second time point as the label. The second time point is later than the first time point, and both are historical time points.

In some embodiments, the gas company management platform may determine different training sets based on a quantity of sample associated pipeline groups in the sample pipeline graph and a quantity of sample gas pipelines contained in the sample associated pipeline group; and when training using the different training sets, set different learning rates to improve the convergence speed of the model training.

The training set refers to a set including a plurality of training samples with labels. The larger the size of the training set, the more training samples it includes, and the longer the training time.

In some embodiments, the gas company management platform may preset a plurality of sample quantities based on prior experience, and randomly select a plurality of training samples with labels based on the sample quantities to form a training set.

The learning rate refers to a parameter for controlling a weight update amplitude during model training. The larger the learning rate, the faster the model converges.

In some embodiments, the learning rate of the training set may be negatively correlated with a quantity of sample associated pipeline groups in the sample pipeline graph, and negatively correlated with a quantity of sample gas pipelines contained in the sample associated pipeline group.

In some embodiments, the gas company management platform may obtain a plurality of training samples with labels to form a training set and perform a plurality of iterations based on the training set. At least one iteration includes: selecting one or more training samples from the training set; inputting the one or more training samples into an initial pipeline liquid accumulation model to obtain one or more model prediction outputs corresponding to one or more training samples; substituting the labels of the one or more training samples and corresponding model prediction outputs into a preset loss function formula to determine the value of the loss function; iteratively updating model parameters of the initial pipeline liquid accumulation model based on the value of the loss function and the learning rate of the training set until an iteration termination condition is satisfied; terminating the iteration to obtain the trained pipeline liquid accumulation model 530. Iteratively updating the model parameters of the initial pipeline liquid accumulation model may be performed by a plurality of manners. For example, the model parameters may be updated based on a gradient descent manner. The iteration termination condition may include convergence of the loss function, or the number of iterations reaching an iteration number threshold, or the like.

In some embodiments of the present disclosure, by using the pipeline liquid accumulation model 530, the data processing capability and the data analysis capability of the model can be fully utilized to obtain accurate and reliable prediction results in a short time, which can help to quickly determine the liquid accumulation volume 450 of each of the gas pipelines in the associated pipeline group 510.

The basic concepts have been described above. It is apparent to a person skilled in the art that the detailed disclosure presented above is merely by way of example and does not constitute a limitation of the present disclosure. Although not explicitly stated herein, a person skilled in the art may make various modifications, improvements, and revisions to the present disclosure. Such modifications, improvements, and revisions are suggested in the present disclosure, and therefore, they still fall within the spirit and scope of the exemplary embodiments of the present disclosure.

Meanwhile, the present disclosure uses specific terms to describe embodiments of the present disclosure. For example, ‘an embodiment’, ‘one embodiment’, and/or ‘some embodiments’ mean a certain feature, structure, or characteristic related to at least one embodiment of the present disclosure. Therefore, it should be emphasized and noted that the phrases ‘one embodiment’ or ‘an embodiment’ or ‘an alternative embodiment’ mentioned twice or more in different places in the present disclosure do not necessarily refer to the same embodiment. Furthermore, certain features, structures, or characteristics in one or more embodiments of the present disclosure may be appropriately combined.

Furthermore, unless explicitly stated in the claims, the order of processing elements and sequences described in the present disclosure, the use of alphanumeric characters, or the use of other names is not intended to limit the order of processes and manners of the present disclosure. Although some presently useful embodiments have been discussed through various examples in the disclosure described above, it should be understood that such details are for illustrative purposes only. The appended claims are not limited to the disclosed embodiments; instead, the claims are intended to cover all modifications and equivalent combinations that fall within the spirit and scope of the embodiments of the present disclosure. For example, although the system components described above may be implemented by hardware devices, they may also be implemented only through software solutions, such as by installing the described system on existing servers or mobile devices.

Similarly, it should be noted that, in order to simplify the expression in the present disclosure and thereby facilitate an understanding of one or more embodiments of the present disclosure, the preceding description of the embodiments of the present disclosure may sometimes group various features into a single embodiment, drawing, or description thereof. However, this manner of disclosure does not imply that the features required by the subject matter of the present disclosure are more numerous than the features recited in the claims. In fact, the features of the embodiments are fewer than all of the features of a single embodiment described in the foregoing disclosure.

In some embodiments, numerical values that describe quantities of components or attributes are used. It should be understood that such numerical values used for describing embodiments are modified by the terms ‘approximately’, ‘proximate’, or ‘substantially’ in some examples. Unless otherwise stated, ‘approximately’, ‘proximate’, or ‘substantially’ indicate that the numerical values allow for a variation of ±20%. Accordingly, in some embodiments, the numerical parameters used in the disclosure and claims are approximate values, and the approximate values may be changed according to the desired characteristics of individual embodiments. In some embodiments, the numerical parameters should consider the specified significant digits and adopt a general manner of digit retention. Although the numerical ranges and parameters used to confirm the breadth of their scope are approximate values in some embodiments of the present disclosure, in specific embodiments, the setting of such numerical values is as precise as possible within the feasible range.

Each patent, patent application, patent application publication, and other materials cited in the present disclosure, such as articles, books, disclosures, publications, and documents, or the like, is hereby incorporated by reference in their entirety into the present disclosure. Excluded are any prosecution history documents inconsistent with or conflicting with the content of the present disclosure, and also excluded are any documents (currently or later appended to the present disclosure) that limit the broadest scope of the claims of the present disclosure. It should be noted that if there are any inconsistencies or conflicts between the description, definitions, and/or use of terms in the ancillary materials of the present disclosure and the content described in the present disclosure, the description, definitions, and/or use of terms of the present disclosure shall govern.

Finally, it should be understood that the embodiments described in the present disclosure are merely for illustrating the principles of the embodiments of the present disclosure. Other variations may also fall within the scope of the present disclosure. Accordingly, by way of example and not by way of limitation, alternative configurations of the embodiments of the present disclosure may be considered as being consistent with the teachings of the present disclosure. Accordingly, the embodiments of the present disclosure are not limited to the embodiments explicitly introduced and described in the present disclosure.

What is claimed is:

1. An Internet of Things system for liquid accumulation supervision in smart gas pipelines, comprising a gas company management platform, a gas company sensor network platform, and a gas device object platform, wherein
the gas company management platform is configured to:
obtain gas sampling information from a storage device in a gas gate station at an upstream of a gas pipeline, wherein the gas sampling information is obtained by a sampling device sampling at a gas valve;
determine a cumulative transmission time based on a sampling time point automatically recorded and uploaded by a gas auxiliary facility;
determine a liquid accumulation volume in an interior of the gas pipeline based on the gas sampling information and the cumulative transmission time, and mark the liquid accumulation volume at positions of different pipeline models in a Geographic Information System (GIS); and
in response to determining that the liquid accumulation volume in the interior of the gas pipeline increases to a preset volume threshold, determine a valve opening adjustment amount and control a pressure regulating valve of the gas gate station to move based on the valve opening adjustment amount to reduce a valve opening, or issue an instruction to the gas gate station to replace a filter element of a gas filtration device so as to reduce a liquid accumulation generation rate in a gas pipeline downstream of the gas gate station; and remotely control a liquid accumulation supervision device to open an automatic blowdown valve to reduce the liquid accumulation volume in the gas pipeline.

2. The system according to claim 1, wherein the gas company management platform is further configured to:
control a pipeline robot to travel in the gas pipeline, wherein the pipeline robot is configured with a force sensor;
obtain resistance data uploaded by the pipeline robot via a wireless communication device of the gas company sensor network platform;
determine a current liquid accumulation volume in the interior of the gas pipeline based on the resistance data;
determine an estimated liquid accumulation volume in the interior of the gas pipeline at a future time point based on the current liquid accumulation volume, the gas sampling information, and the cumulative transmission time;
update an opening cycle of the automatic blowdown valve according to the estimated liquid accumulation volume; and,
control the automatic blowdown valve in each of liquid accumulation supervision devices to operate based on an updated opening cycle.

3. The system according to claim 2, wherein the gas company management platform is further configured to:
determine a pipeline travel path of the pipeline robot based on the opening cycle of the automatic blowdown valve, wherein the pipeline travel path comprises sequence data composed of pipeline numbers and pipeline location coordinates in the GIS.

4. The system according to claim 1, wherein the gas company management platform is further configured to:
obtain gas transmission information from the gas gate station via the gas company sensor network platform, wherein the gas transmission information comprises a gas transmission rate and a gas temperature;
generate an associated pipeline group based on gas pipelines, and mark a pipeline model in the GIS, wherein the associated pipeline group refers to gas pipelines having a pipeline connectivity relationship;
determine a liquid accumulation volume of each of the gas pipelines in the associated pipeline group based on the gas transmission information, the gas sampling information, and the cumulative transmission time; and
jointly regulate an opening cycle of each of automatic blowdown valves configured in the associated pipeline group according to the liquid accumulation volume.

5. The system according to claim 4, wherein the gas company management platform is further configured to:
determine a liquid accumulation coefficient of each of the gas pipelines based on an adjacency degree of a gas pipeline in the associated pipeline group to a most upstream pipeline, a liquid accumulation change rate of each of the gas pipelines, and the gas transmission information; and
determine the liquid accumulation volume in an interior of the gas pipeline in the associated pipeline group based on the cumulative transmission time, the liquid accumulation change rate, and the liquid accumulation coefficient.

6. The system according to claim 4, wherein the gas company management platform is further configured to:
construct a pipeline graph based on the associated pipeline group, the gas sampling information, the cumulative transmission time, and the gas transmission information corresponding to the gas pipeline in the associated pipeline group; and
determine the liquid accumulation volume of each of the gas pipelines in the associated pipeline group based on the pipeline graph through a pipeline liquid accumulation model, wherein the pipeline liquid accumulation model is a machine learning model.

7. The system according to claim 6, wherein an attribute of a node in the pipeline graph comprises a historical liquid accumulation volume when the pipeline robot collects the resistance data.

8. The system according to claim 6, wherein the pipeline liquid accumulation model is obtained through model training including:
determining different training sets based on a quantity of sample associated pipeline groups in a sample pipeline graph and a quantity of sample gas pipelines contained in each of the sample associated pipeline groups; and
setting different learning rates when training with the different training sets to improve a convergence speed of the model training.

9. The system according to claim 1, wherein the gas company management platform is further configured to:
determine an opening time point of the automatic blowdown valve of the liquid accumulation supervision device in each of the gas pipelines based on the liquid accumulation volume in the interior of the gas pipeline;
determine an opening sequence based on opening time points;
remotely open the automatic blowdown valve of a corresponding liquid accumulation supervision device sequentially based on the opening sequence to discharge the liquid accumulation in the gas pipeline; and
activate a to-be-activated liquid accumulation supervision device of a to-be-constructed gas pipeline based on liquid accumulation volume data in the interior of the gas pipeline and an opening record of the automatic blowdown valve of the liquid accumulation supervision device.

10. The system according to claim 9, wherein the gas company management platform is further configured to:
determine the opening sequence of the automatic blowdown valve of each of liquid accumulation supervision devices at a future time point based on the estimated liquid accumulation volume.

11. A method for liquid accumulation supervision in smart gas pipelines, wherein the method is executed based on a gas company management platform, the method comprising:
obtaining gas sampling information from a storage device in a gas gate station at an upstream of the gas pipeline, wherein the gas sampling information is obtained by a sampling device sampling at a gas valve;
determining a cumulative transmission time based on a sampling time point automatically recorded and uploaded by a gas auxiliary facility;
determining a liquid accumulation volume in an interior of the gas pipeline based on the gas sampling information and the cumulative transmission time, and marking the liquid accumulation volume at positions of different pipeline models in a Geographic Information System (GIS); and
in response to the liquid accumulation volume in the interior of the gas pipeline increasing to a preset volume threshold, determining a valve opening adjustment amount and controlling a pressure regulating valve of the gas gate station to move based on the valve opening adjustment amount to reduce a valve opening, or issuing an instruction to the gas gate station to replace a filter element of a gas filtration device to reduce a liquid accumulation generation rate of the gas pipeline downstream of the gas gate station; and remotely controlling a liquid accumulation supervision device to open an automatic blowdown valve to reduce the liquid accumulation volume in the gas pipeline.

12. The method according to claim 11, further comprising:
controlling a pipeline robot to travel in the gas pipeline, wherein the pipeline robot is configured with a force sensor;
obtaining resistance data uploaded by the pipeline robot via a wireless communication device of a gas company sensor network platform;
determining a current liquid accumulation volume in the interior of the gas pipeline based on the resistance data;
determining an estimated liquid accumulation volume in the interior of the gas pipeline at a future time point based on the current liquid accumulation volume, the gas sampling information, and the cumulative transmission time;
updating an opening cycle of the automatic blowdown valve according to the estimated liquid accumulation volume; and
controlling the automatic blowdown valve in each of liquid accumulation supervision devices to operate based on an updated opening cycle.

13. The method according to claim 12, further comprising:
determining a pipeline travel path of the pipeline robot based on the opening cycle of the automatic blowdown valve, wherein the pipeline travel path comprises sequence data composed of pipeline numbers and pipeline location coordinates in the GIS.

14. The method according to claim 11, wherein the determining a liquid accumulation volume in an interior of the gas pipeline based on the gas sampling information and the cumulative transmission time, and marking the liquid accumulation volume at positions of a different pipeline models in a Geographic Information System (GIS) comprises:
acquiring gas transmission information from the gas gate station and a gas pressure regulating station through a gas company sensor network platform, wherein the gas transmission information comprises a gas transmission rate and a gas temperature;
generating an associated pipeline group based on gas pipelines, and marking the pipeline models in the GIS, wherein the associated pipeline group refers to gas pipelines having a pipeline connectivity relationship;
determining a liquid accumulation volume of each of the gas pipelines in the associated pipeline group based on the gas transmission information, the gas sampling information, and the cumulative transmission time; and
jointly controlling an opening cycle of each of automatic blowdown valves included in the associated pipeline group according to the liquid accumulation volume.

15. The method according to claim 14, wherein the determining a liquid accumulation volume of each of the gas pipelines in the associated pipeline group based on the gas transmission information, the gas sampling information, and the cumulative transmission time comprises:
determining a liquid accumulation coefficient of each of the gas pipelines based on an adjacency degree of a gas pipeline in the associated pipeline group to a most upstream pipeline, a liquid accumulation change rate of each of the gas pipelines, and the gas transmission information; and
determining a liquid accumulation volume in an interior of each of the gas pipelines in the associated pipeline group based on the cumulative transmission time, the liquid accumulation change rate, and the liquid accumulation coefficient.

16. The method according to claim 14, wherein the determining a liquid accumulation volume of each of the gas pipelines in the associated pipeline group based on the gas transmission information, the gas sampling information, and the cumulative transmission time comprises:
constructing a pipeline graph based on the associated pipeline group, gas sampling information, the cumulative transmission time, and the gas transmission information corresponding to each of the gas pipelines in the associated pipeline group; and
determining a liquid accumulation volume of each of the gas pipelines in the associated pipeline group based on the pipeline graph through a pipeline liquid accumulation model.

17. The method according to claim 16, wherein an attribute of a node in the pipeline graph further comprises a historical liquid accumulation volume when a pipeline robot collects resistance data.

18. The method according to claim 16, wherein the pipeline liquid accumulation model is obtained through model training including:
determining different training sets based on a quantity of sample associated pipeline groups in a sample pipeline graph and a quantity of sample gas pipelines contained in each of the sample associated pipeline groups; and
setting different learning rates when training using the different training sets to improve a convergence speed of the model training.

19. The method according to claim 11, further comprising:
determining an opening time point of the automatic blowdown valve of the liquid accumulation supervision device in each of the gas pipelines based on the liquid accumulation volume in the interior of the gas pipeline;
determining an opening sequence based on opening time points;
remotely opening an automatic blowdown valve of a corresponding liquid accumulation supervision device in sequence based on the opening sequence to discharge pipeline liquid accumulation; and
activating one or more additional liquid accumulation supervision devices of a to-be-constructed gas pipeline based on liquid accumulation volume data in the interior of the gas pipeline and an opening record of the automatic blowdown valve of the liquid accumulation supervision device.

20. The method according to claim 19, wherein the determining the opening sequence further comprises:
determining the opening sequence of the automatic blowdown valve of each of the liquid accumulation supervision devices at a future time point based on an estimated liquid accumulation volume.
